(19) United States
(12) Patent Application Publication
(10) Pub. No.: US 2021/0050191 A1
(43) Pub. Date: Feb. 18, 2021

(54) METHODS AND SYSTEMS FOR PLASMA PROCESSING TOOL MATCHING AFTER PREVENTATIVE MAINTENANCE

(71) Applicant: Tokyo Electron Limited, Tokyo (JP)

(72) Inventors: Kenichi Usami, Miyagi (JP); Norihisa Kiyofuji, Miyagi (JP); Hiroto Otake, Miyagi (JP); Shinji Ide, Hillsboro, OR (US); Jun Shinagawa, Fremont, CA (US)

(21) Appl. No.: 16/538,338

(22) Filed: Aug. 12, 2019

(51) Int. Cl. H01J 37/32; H01L 21/67

(52) U.S. Cl. CPC H01J 37/32926; H01J 2237/334; H01J 37/32972; H01L 21/67253

(57) ABSTRACT

Embodiments are described herein for systems and methods for plasma processing tool matching after preventative maintenance (PM). Before the PM, the plasma processing tool is operated to run a process on a test wafer, and measurements are taken for pre-PM operational data associated with the process during the operating. After the PM, the plasma processing tool is again operated to run the process on a test wafer, and measurements are taken for post-PM operational data associated with the process during the operating. A prediction model is then applied to the pre-PM operational data and the post-PM operational data to generate an estimated difference in a product parameter, and the prediction model is configured to provide an estimate for the product parameter based upon operational data. One or more control settings for the plasma processing tool are then adjusted to compensate for the estimated difference in the product parameter.

### BACKGROUND

The present disclosure relates to methods for the manufacture of microelectronic workpieces including the formation of patterned structures on microelectronic workpieces.

Device formation within microelectronic workpieces typically involves a series of manufacturing techniques related to the formation, patterning, and removal of a number of layers of material on a substrate. To meet the physical and electrical specifications of current and next generation semiconductor devices, process flows are being requested to reduce feature size while maintaining structure integrity for various patterning processes.

Plasma processing tools are used in the manufacture of microelectronic workpieces. Plasma processing tools require periodic preventative maintenance (PM) to maintain performance. After PM work is completed, plasma processing tools typically require tuning to match post-process structural profiles such as critical dimension (CD) profiles against pre-PM operations and/or other operating plasma processing tools. This tuning processing is commonly referred to as a post-PM tool matching process. The post PM tool matching process is often costly and time consuming because tool matching process and hardware (HW) control knobs are tuned iteratively based on actual metrology measurements made to patterned structures on test wafers after runs through the plasma processing tool. It is noted for one example that CD profiles to be matched can include one or more feature dimensions such as width, length sidewall angle, feature depth, and/or other feature dimensions.

To minimize device performance variabilities, variabilities in the post-process structural profiles among plasma processing tools, such as CD profiles, are tightly controlled during production runs. However, such tight control is lost after PM as the tool conditions are significantly altered by PM work such as breaking vacuum and replacing consumable parts. These altered chamber conditions result in loss of the profile control. As such, significant time and resources are spent to re-establish this control after PM work, which is commonly referred to as post-PM recovery. For example, CD profiles can be tuned during post-PM recovery to target values by re-adjusting recipe parameters, and this is typically achieved by running pattern wafers iteratively through the processing chamber. These runs using pattern wafers, however, are costly and time-consuming.

FIG. 1 (Prior Art) represents an example embodiment 100 for a prior solution where post-PM recovery is based upon direct metrology measurements of a product parameter, such as CD profile data, that are made after pattern wafer runs using a run-to-run control application. For this control application, process parameters are adjusted run-to-run based upon metrology-based measurements made to the pattern wafer after each run. Looking in more detail to embodiment 100, productions runs are conducted in block 102. In block 104, a pre-PM run is conducted using a pattern wafer. In block 106, data is collected and stored for a product parameter through direct measurements using metrology tools. In block 108, PM work is performed on the process equipment and related process chamber. After PM work has completed, a post-PM run is conducted using a pattern wafer in block 110. In block 112, data is collected and stored for the product parameter through direct measurements using metrology tools. The pre-PM metrology data and the post-PM metrology data is compared in block 116, and these comparisons are used to adjust process controls. As indicated by loop 114, this is repeated until the post-PM metrology data is deemed to be within acceptable variations from the pre-PM metrology data. Upon completion of the post-PM qualification processing, as indicated by arrow 118, a return to production runs is achieved in block 120. Many repeated runs are typically required in loop 114, and each run in block 110 requires a pattern wafer. This repeated processing required to reach completion is time-consuming and expensive.

### SUMMARY

Embodiments are described herein for systems and methods for plasma processing tool matching after preventative maintenance (PM). The disclosed embodiments reduce the cost and the time required for the post-PM tool matching process by replacing the metrology-based tool matching process with a virtual metrology (VM) tool matching process based upon prediction models. For the disclosed embodiments, a prediction model estimates the product parameter based upon operational data collected from the plasma processing tool or process chamber during test wafer runs made before and after the PM work (e.g., pre-PM run and post-PM run). For example, a CD prediction model can be used to estimate CD changes, and adjustments can be made to compensate for these estimated CD changes. Adjustment to process parameters or control knobs for the plasma processing tool are determined by differences in the estimated product parameters. These adjustments can also be based upon previously established correlations of operational data with the control knobs. The application of prediction models to the post-PM tool matching as described herein also help to compensate for non-linear abrupt modifications to operational data between pre-PM runs and post-PM runs that can cause significant errors. Different or additional features, variations, and embodiments can also be implemented, and related systems and methods can be utilized as well.

For one embodiment, a method is disclosed to adjust operation of a plasma processing tool. Before preventative maintenance (PM) for the plasma processing tool, the method includes operating the plasma processing tool to run a process on a first test wafer and measuring pre-PM operational data associated with the process during the operating. After PM for the plasma processing tool, the method includes operating the plasma processing tool to run the process on a second test wafer, measuring post-PM operational data associated with the process during the operating. The method then includes applying a prediction model to the pre-PM operational data and the post-PM operational data to generate an estimated difference in a product parameter, where the prediction model is configured to provide an estimate for the product parameter based upon measured operational data, and adjusting one or more control settings for the plasma processing tool to compensate for the estimated difference in the product parameter.

In additional embodiments, the measuring is performed using one or more sensors associated with the plasma processing tool. In further embodiments, the one or more sensors are located outside a process chamber for the plasma processing tool, inside the process chamber, or both outside and inside the process chamber. In further embodiments, the one or more sensors include an optical emission spectrometry (OES) sensor.

In additional embodiments, the one or more control settings are configured to adjust process parameters for a process chamber for the plasma processing tool. In further embodiments, the adjusting includes adjusting a plurality of control knobs for the plasma processing tool. In further embodiments, the one or more control settings are associated with at least one of microwave (MW) power, radio frequency (RF) power, gas chemistry flows, direct current (DC) biases, chamber pressure, or chamber temperature.

In additional embodiments, the first and second test wafers include a blanket wafer having one or more material layers. In further embodiments, the one or more material layers include at least one of a silicon oxide layer or a polysilicon layer.

In additional embodiments, the prediction model is configured to estimate a critical dimension (CD) as the product parameter. In further embodiments, the pre-PM operational data and the post-PM operational data each includes at least one of optical emission spectrometry (OES) data, gas flow rate data, pressure data, or temperature data.

In additional embodiments, the prediction model is based at least in part upon optical emission spectrometry (OES) wavelengths associated with etchants, passivates, or etch by-products associated with the process. In further embodiments, the prediction model is based upon a determination of control settings that are most sensitive for the product parameter being estimated using the prediction model. In further embodiments, the prediction model is based upon a regression on data collected in multiple experimental runs of the plasma processing tool.

In additional embodiments, the method includes matching one or more control settings across multiple plasma processing tools.

In additional embodiments, the method further includes, after the PM for the plasma processing tool, repeating the operating, measuring, storing, applying, and adjusting until a target result is achieved for the product parameter. In further embodiments, the target result includes an estimated difference that is within an acceptable difference amount. In further embodiments, the method includes measuring the product parameter using a metrology tool after the repeating to determine if the target result for the product parameter is achieved.

In additional embodiments, the method includes performing the preventative maintenance. In further embodiments, the preventative maintenance includes at least one of replacing consumable parts, performing clean operations such as a wet clean operation, or pulling and re-sealing vacuum connections.

Different or additional features, variations, and embodiments can also be implemented, and related systems and methods can be utilized as well.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (Prior Art) provides an example embodiment for a prior solution where post-PM recovery is based upon direct metrology measurements of a product parameter, such as CD profile data, that are made after pattern wafer runs using a run-to-run control application.

FIG. 2A provides an example embodiment for novel solutions described herein where post-PM recovery is based upon prediction models applied to operational data collected from test wafer runs and where estimated differences based upon pre-PM data and post-PM data are used to adjust process controls to achieve target results for product parameters.

FIG. 2B provides an example embodiment with further details for the execution of the post-PM recovery process of FIG. 2A for a plasma processing tool.

FIG. 3 provides one example embodiment for a plasma processing tool that can be used with respect to the disclosed techniques and is provided only for illustrative purposes.

FIG. 4 provides an example embodiment for a first step in the building of a prediction model where optical emission spectrometry (OES) wavelength data is determined for etchants, passivants, and by-products for a recipe to be run in the plasma processing tool.

FIG. 5 provides an example embodiment for a second step in the building of a prediction model where a design of experiment (DOE) is executed to determine the most sensitive control knobs against variations in the product parameter.

FIG. 6 provides an example embodiment for a third step in the building of a prediction model where the prediction model is built through regression analysis of operational data measured and collected during the DOE runs described in FIG. 5.

### DETAILED DESCRIPTION

Methods and systems are disclosed for plasma processing tool matching after preventative maintenance (PM) where prediction models are used to estimate product parameters based upon test wafer runs in the plasma processing tool. The prediction models are applied to provide post-PM tool matching in contrast with prior solutions where run-to-run control is applied based upon metrology-based measurements. A variety of advantages and implementations can be achieved while taking advantage of the process techniques described herein.

It is noted that the example embodiments described herein focus on CD as the product parameter being adjusted. It is noted for one example that CD profiles to be matched can include one or more feature dimensions such as width, length, sidewall angle, feature depth, and/or other feature dimensions. For example, with respect to a gate for a transistor device, CD can include top, middle, and bottom widths of the gate as well as the gate-related width at the height level for other structures associated with the transistor feature. Further, CD profiles can include two-dimensional (2D) features, three-dimensional (3D) features, or both 2D and 3D features. It is also understood that CD is used as one example, and other product parameters can also be used in addition to and/or instead of CD. For example, an etch rate, etch selectivity, or other parameters can be used. The etch rate, for example, can be a film removal rate in a selected direction, such as a vertical direction. The etch selectivity, for example, can be a ratio of etch rates for two types of film. It is further noted that the embodiments described below focus on the use of blanket wafers rather than pattern wafers as with prior solutions. Blanket wafers are test wafers that include one or more films or material layers, such as a material layer of silicon oxide and/or a material layer of polysilicon. Use of blanket wafers rather than pattern wafers substantially reduces cost. Other test wafers, however, could also be used instead of blanket wafers. Other variations can also be implemented while still taking advantage of the techniques described herein.

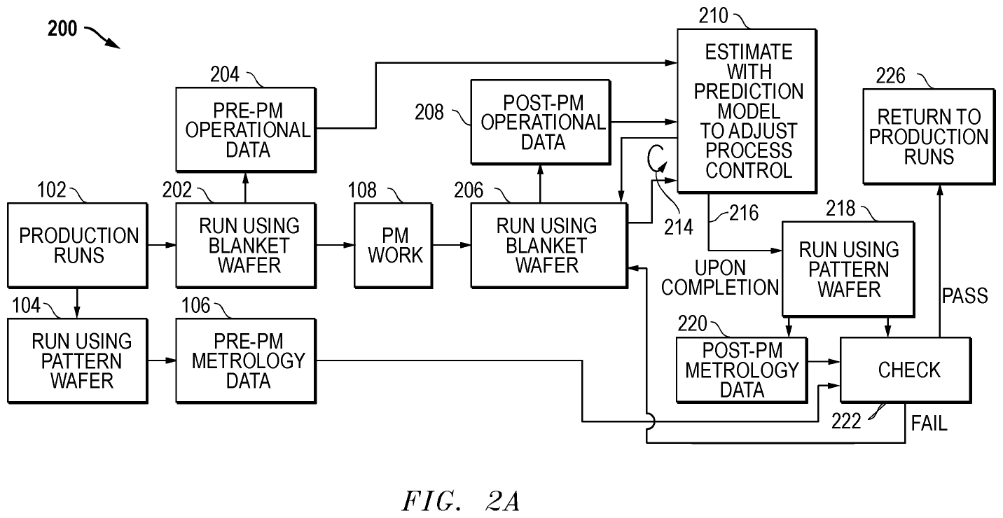

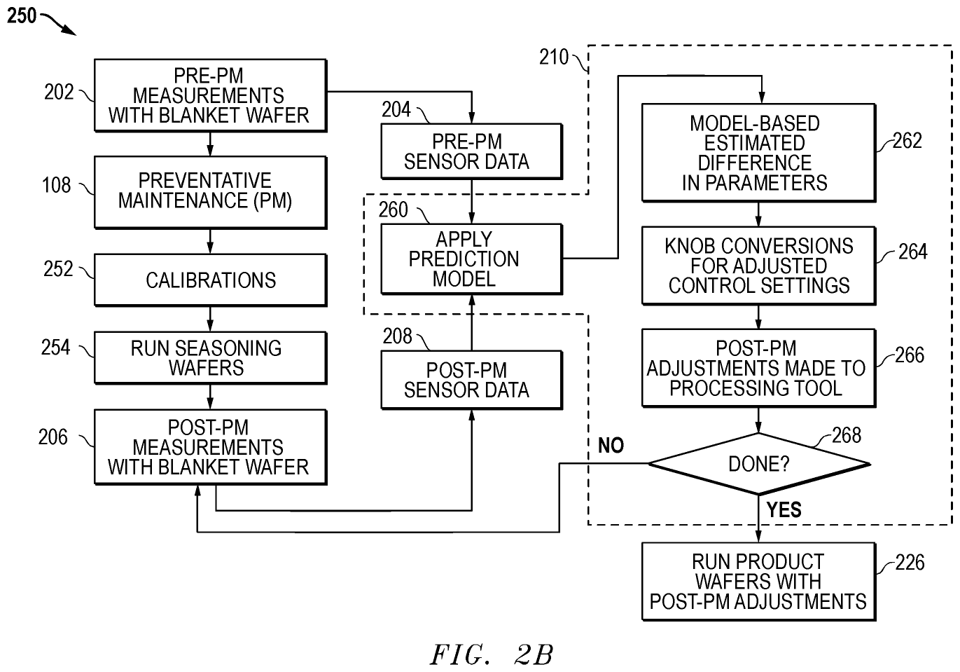

FIG. 2A provides an example embodiment 200 for the novel solutions described herein where prediction models are applied to operational data collected from test wafer runs and where estimated differences based upon pre-PM data and post-PM data are used to adjust process controls to achieve target results for product parameters. For example, CD matching is performed using a CD prediction model based upon measured operational data such as optical emission spectrometry (OES) data, gas flow rate data, pressure data, temperature data, and/or other collected data. As such, the disclosed embodiments are able to predict the CD profile after PM work by using prediction models and inexpensive blanket wafers for cost improvement, and the disclosed embodiments enable adjustment to process controls based upon these prediction models.

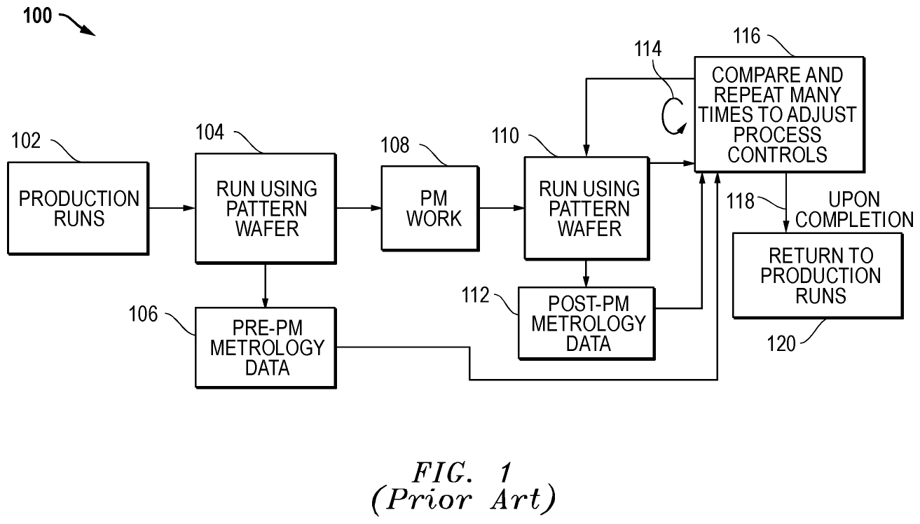

Looking in more detail to FIG. 2A, blocks 102, 104, 106, and 108 are similar to embodiment 100 in FIG. 1 (Prior Art). Productions runs are conducted in block 102. In block 104, a pre-PM run is conducted using a pattern wafer. In block 106, data is collected and stored for a product parameter using metrology tools. In contrast to prior solutions, however, a pre-PM run is conducted using a blanket wafer in block 202 prior to the PM work in block 108. Operational data associated with this pre-PM run is collected and stored in block 204. After PM work has completed in block 108, a post-PM run is conducted using a blanket wafer in block 206. Operational data associated with this post-PM run is collected and stored in block 208. In block 210, a prediction model is used to estimate parameter differences generated by pre-PM and post-PM processes. These estimations are used to adjust process controls. As indicated by loop 214, this process is repeated until target results are achieved. For example, the process can be repeated until the parameter differences generated using the prediction model are deemed to be within acceptable difference amounts. For one example embodiment, a percentage difference between the estimates as compared to a selected percentage to determine if the difference is within an acceptable difference amount, such that the following is satisfied:

$$\vert \frac{( postPM\_estimate - prePM\_estimate )}{prePM\_estimate} \vert \leq percentage$$

The selected percentage can be 5 percent or more preferably 1 percent, although other percentages can also be used. For one example embodiment, a difference between the estimates as compared to a selected threshold is used to determine if the difference is an acceptable difference amount, such that the following is satisfied:

|postPM_estimate−prePM_estimate|≤threshold

For one example where CD is the parameter being analyzed, a threshold of 0.2 nanometers is used, although other threshold amounts can also be used. It is further noted that additional or different determination techniques can also be used while still taking advantage of the techniques described herein.

Upon completion of the sensor and model based processing, as indicated by arrow 216, an additional run is conducted using a pattern wafer in block 218. In block 220, data is collected and stored for the product parameter using metrology tools. The pre-PM metrology data and the post-PM metrology data is compared in block 222 as a secondary check for the model-based processing. This secondary check can determine if the metrology-based measurement shows that the post-PM metrology data is within acceptable differences from the pre-PM metrology data. If this check is deemed to “FAIL,” block 206 can be reached where the model-based processing is again initiated. If the check is deemed a “PASS,” a return to production runs is achieved in block 226.

It is noted that the operational data collected for the pre-PM operational data in block 204 and the post-PM-operational data in block 208 can include a variety of process related operational data. For example, optical emission spectrometry (OES) data, gas flow rate data, pressure data, temperature data, and/or other operational data can be collected using one or more sensors associated with the plasma processing tool. As described herein, this operational data is sensed, collected, and stored during runs with blanket wafers loaded within the plasma processing tool. It is again noted that other types of test wafers could also be used.

Although repeated runs may still be required in loop 214, each of these runs in block 206 only require a blanket wafer, and a prediction model is used rather than direct metrology-based measurements. As such, expense is reduced and cycle time is greatly reduced as compared to prior solutions. Rather than require many pattern wafers and related processing runs to adjust process controls, the embodiment 200 uses a pattern wafer only as a check to process controls adjusted using the model-based processing. It is also noted that the pattern wafer processing in blocks 104 and 218 could also be removed for embodiments where a secondary check is not implemented. For such an embodiment, the return to production in block 226 occurs after the completion of the loop 214 and the model-based processing in block 210. Other variations could also be implemented while still taking advantage of the sensor-based and model-based processing described herein.

FIG. 2B provides an example embodiment 250 with further details for the execution of the post-PM tool matching process for a plasma processing tool. In block 202, operational data for the plasma processing tool (e.g., OES, temperature, chamber pressure, gas flow rate, etc.) are measured, collected, and stored as reference data during blanket wafer runs before the start of PM work 108. For example, a run can be performed with a blanket wafer using a selected process recipe having certain etching conditions or deposition conditions. In block 206, the same set of measurements is taken during blanket wafer runs after the PM work 108. As indicated in FIG. 2A, a prediction model is used in block 210 to estimate parameter differences generated by pre-PM and post-PM processes, and these estimates are used to adjust process controls.

The operation for block 210 is shown in more detail in embodiment 250. In block 260, the pre-PM operational data from block 204 and the post-PM operational data from block 206 are applied to the prediction model. As represented by block 262, the prediction model generates a model-based estimated difference in a product parameter based upon the pre-PM and post-PM operational data. For example, the pre-PM operational data from block 204 is provided to the prediction model, and the prediction model outputs a pre-PM estimated value for the product parameter. Similarly, the post-PM operational data from block 208 is provided to the prediction model, and the prediction model outputs a post-PM estimated value for the product parameter. The difference between the pre-PM estimated value and the post-PM estimated value provides an estimated difference in product parameter before and after the PM work 108. Again, this estimated difference is based upon the pre-PM operational data from block 204 and the post-PM operational data from block 208 as applied to the prediction model. Conversions from this estimated difference are then made in block 264 to determine changes in knobs to provide adjusted control settings to compensate for the estimated difference. In block 266, these post-PM adjustments are then applied to the processing tool for later runs with product wafers. In block 268, a determination is made whether the post-PM processing is done. For example, a determination can be made whether further adjustments or checks are needed to reach target results for the product parameter. If the determination is “NO,” then flow passes back to block 206 for further processing. If the determination is “YES,” then flow passes to block 226 where product wafers are run in the plasma processing tool with the post-PM adjustments.

It is noted that the prediction model applied in block 260 can correlate one or more of the operational measurements being made to the product parameter. Again using CD as an example for the product parameter, the following equation can apply:

P_{CD_EST}=f(M1, M2, . . . MN)

For this equation, P_{CD_EST} represents the estimated product parameter and is a function (f) of one or more different operational measurements represented by M1, M2 . . . MN. The estimated difference in the parameter (ΔP_{CD}) provided in block 262 is based upon the difference between the model-based estimate for the product parameter (P_{CD_EST}) from the pre-PM data and the model-based estimate for the product parameter (P_{CD_EST}) from the pre-PM data. The knobs for which adjustments are determined in block 264 can represent a wide variety of control settings for the plasma processing tool 300. For example, knobs can be controls for microwave (MW) power, radio frequency (RF) power, gas chemistry flows, direct current (DC) biases, chamber pressure, chamber temperature (e.g., electrostatic chuck (ESC) temperature, chamber wall temperature, top plate temperature), and/or other process controls. It is also noted that the amount of adjustments necessary in block 264 for control knobs to compensate for the estimated difference in the parameter (ΔP_{CD}) due to the PM work can be estimated from the data tables collected previously from blanket wafer runs with varied control knobs.

It is noted that the PM work 108 can include one or more maintenance actions taken on the plasma processing tool. These actions can include replacing consumable parts, performing clean operations such as a wet clean operation, pulling and re-sealing vacuum connections, and/or other maintenance actions. It is further noted that calibrations can be performed in block 252 and runs with seasoning wafers can be performed in block 254 after the PM work 108 and before the post-PM measurements are re-taken in block 206. Other variations can also be implemented while still taking advantage of the techniques described herein.

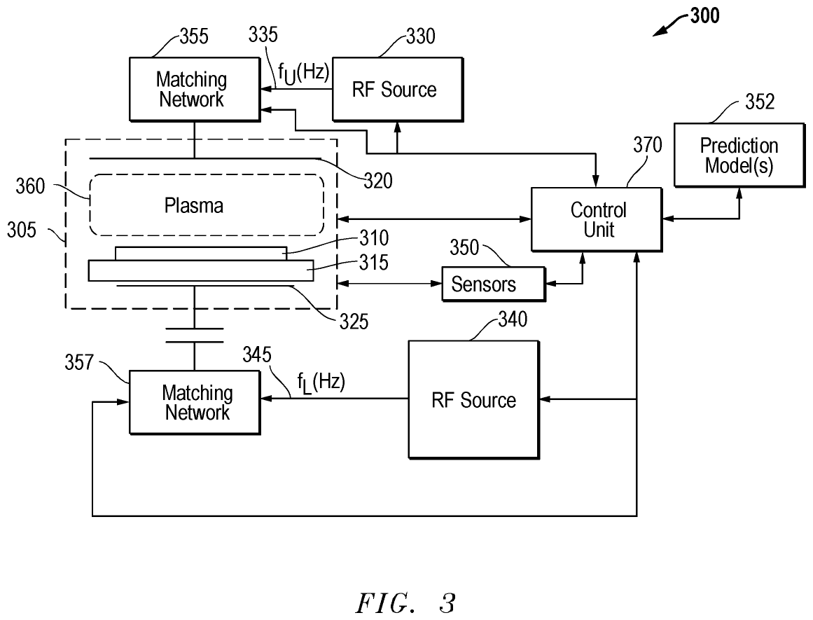

FIG. 3 provides one example embodiment for a plasma processing tool 300 that can be used with respect to the disclosed techniques and is provided only for illustrative purposes. The plasma processing tool 300 may be a capacitively coupled plasma processing apparatus, inductively coupled plasma processing apparatus, microwave plasma processing apparatus, Radial Line Slot Antenna (RLSA™) microwave plasma processing apparatus, electron cyclotron resonance (ECR) plasma processing apparatus, or other type of processing system or combination of systems. Thus, it will be recognized by those skilled in the art that the techniques described herein may be utilized with any of a wide variety of plasma processing systems. The plasma processing tool 300 can be used for a wide variety of operations including, but not limited to, etching, deposition, cleaning, plasma polymerization, plasma-enhanced chemical vapor deposition (PECVD), atomic layer deposition (ALD), atomic layer etch (ALE), and so forth. The structure of a plasma processing tool 300 is well known, and the particular structure provided herein is merely of illustrative purposes. It will be recognized that different and/or additional plasma process systems may be implemented while still taking advantage of the techniques described herein.

The plasma processing tool 300 includes one or more sensors 350 that measure the operational data described herein, such as OES data, temperature data, pressure data, gas flow rate data, and/or other data associated with operation of the plasma processing tool 300. The one or more sensors 350 can include an OES sensor, a pressure sensor, a temperature sensor, a flow rate sensor, and/or other sensors. It is also noted that the sensors 350 can be located inside the process chamber 305, outside the process chamber 305, or both inside and outside the processing chamber 305. Further, one or more prediction models for one or more product parameters can be stored in data storage medium 352. The control unit 370 can be configured to use these prediction models to implement the model-based processing described herein, and the control unit 370 can adjust knobs and control settings for the plasma processing tool 300. It is also noted that the adjustments can be manually made as well. Other variations can also be implemented.

Looking in more detail to FIG. 3, the plasma processing tool 300 may include a process chamber 305. As is known in the art, process chamber 305 may be a pressure-controlled chamber. A substrate 310 (in one example a semiconductor wafer) may be held on a stage or chuck 315. An upper electrode 320 and a lower electrode 325 may be provided as shown. The upper electrode 320 may be electrically coupled to an upper radio frequency (RF) source 330 through an upper matching network 355. The upper RF source 330 may provide an upper frequency voltage 335 at an upper frequency (f_{U}). The lower electrode 325 may be electrically coupled to a lower RF source 340 through a lower matching network 357. The lower RF source 340 may provide a lower frequency voltage 345 at a lower frequency (f_{L}). Though not shown, it will be known by those skilled in the art that a voltage may also be applied to the chuck 315.

The components of the plasma processing tool 300 can be connected to, and controlled by, the control unit 370 that in turn can be connected to a corresponding memory storage unit and user interface (all not shown). Various plasma-processing operations can be executed via the user interface, and various plasma processing recipes and operations can be stored in a storage unit. Accordingly, a given substrate can be processed within the plasma-processing chamber with various microfabrication techniques. It will be recognized that since control unit 370 may be coupled to various components of the plasma processing tool 300 to receive inputs from and provide outputs to the components.

The control unit 370 can be implemented in a wide variety of manners. For example, the control unit 370 may be a computer. In another example, the control unit includes one or more programmable integrated circuits that are programmed to provide the functionality described herein. For example, one or more processors (e.g., microprocessor, microcontroller, central processing unit, etc.), programmable logic devices (e.g., complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g., memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

In operation, the plasma processing apparatus uses the upper and lower electrodes to generate a plasma 360 in the process chamber 305 when applying power to the system from the upper RF source 330 and the lower RF source 340. Further, as is known in the art, ions generated in the plasma 360 may be attracted to the substrate 310. The generated plasma can be used for processing a target substrate (such as substrate 310 or any material to be processed) in various types of treatments such as, but not limited to, plasma etching, chemical vapor deposition, treatment of semiconductor material, glass material and large panels such as thin-film solar cells, other photovoltaic cells, organic/inorganic plates for flat panel displays, and/or other applications, devices, or systems.

Application of power results in a high-frequency electric field being generated between the upper electrode 320 and the lower electrode 325. Processing gas delivered to process chamber 305 can then be dissociated and converted into a plasma. As shown in FIG. 3, the exemplary system described utilizes both upper and lower RF sources. For example, high-frequency electric power, for an exemplary capacitively coupled plasma system, in a range from about 3 MHz to 150 MHz or above may be applied from the upper RF source 330 and a low frequency electric power in a range from about 0.2 MHz to 40 MHz can be applied from the lower RF source. Different operational ranges can also be used. Further, it will be recognized that the techniques described herein may be utilized with in a variety of other plasma systems. In one example system, the sources may switched (higher frequencies at the lower electrode and lower frequencies at the upper electrode). Further, a dual source system is shown merely as an example system and it will be recognized that the techniques described herein may be utilized with other systems in which a frequency power source is only provided to one electrode, direct current (DC) bias sources are utilized, or other system components are utilized.

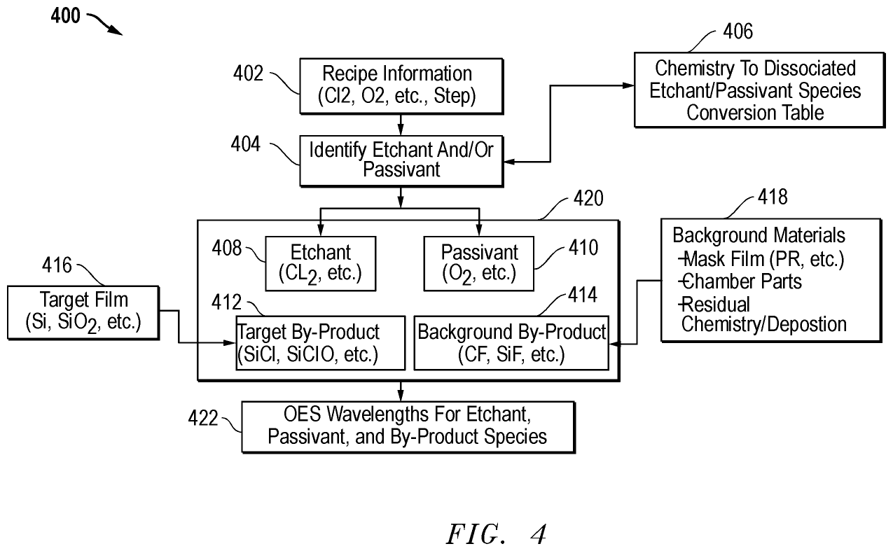

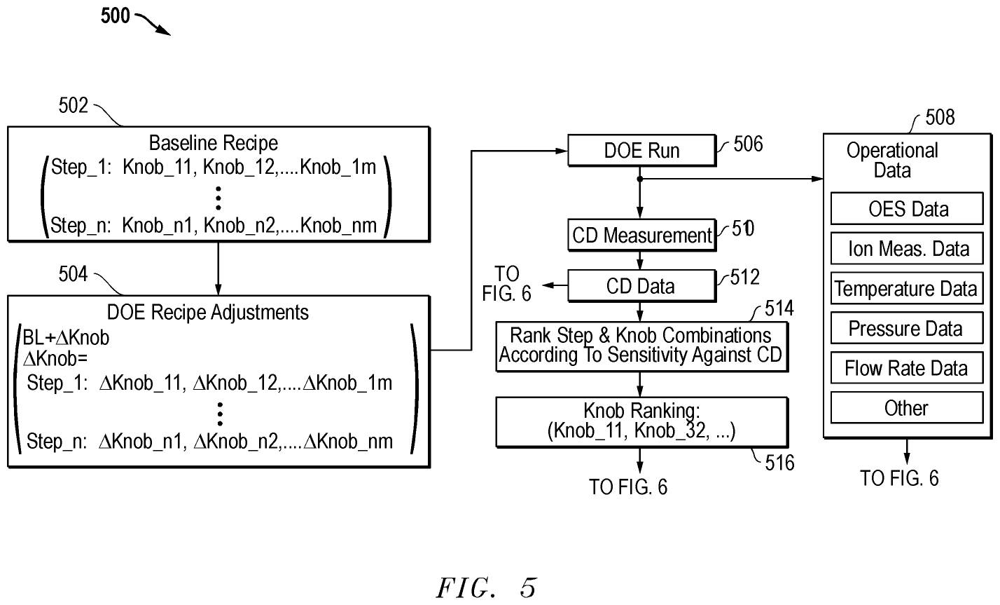

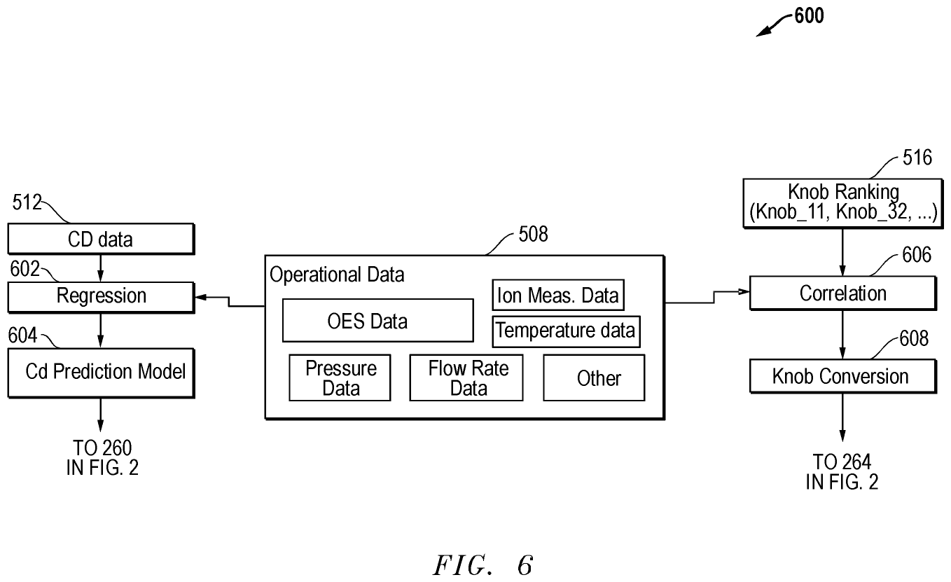

FIGS. 4-6 provide example embodiments for building of a prediction model for a product parameter. For these example embodiments, it is assumed that the product parameter is CD, although it is recognized that a similar technique can be used for other product parameters. For one example implementation, the prediction model building process includes three steps. First, recipe and wafer film stacks are analyzed to determine OES wavelengths for etchants, passivants and by-products as shown in FIG. 4. Second, a design of experiment (DOE) is executed to determine most sensitive control knobs against the CD variations as shown in FIG. 5. And third as shown in FIG. 6, the CD prediction model is built through regression analysis of process diagnostics measurements for operational parameters collected during the DOE runs and through correlations between ranked control knobs and process operational parameters. As described herein, the operational parameters can include optical emission spectra (OES), chamber pressure, gas flow rate, ion measurements, electrostatic chuck (ESC) temperature, and/or other operational parameters. It is noted that other techniques could also be used to build a prediction model while still taking advantage of the techniques described herein.

Looking in more detail to FIG. 4, an example embodiment 400 is provided where OES wavelength data is determined for etchants, passivants, and by-products for a recipe to be run in the plasma processing tool. In block 402, recipe information is collected such as recipe chemistries (Cl₂, O₂, etc.) and recipe steps (STEP). In block 404, the recipe chemistries are identified as etchants and/or passivants. For this identification, a conversion table 406 can be used that correlates recipe chemistry to disassociated etchants and passivants. The resulting etchants 408 and passivants 410 are included within block 420 that identifies target materials for OES wavelength detection. In block 416, target films (e.g., Si, SiO₂, etc.) for the process recipe are identified, and target by-products (e.g., SiCl, SiClO, etc.) of the target films are identified. The target by-products 412 are included within block 420. In block 418, background materials are identified such as mask films (e.g., photoresists, etc.), chamber parts, residual chemistry/deposition materials, and/or other background information. Background by-products 414 for these background materials are also included within block 420. In block 422, OES wavelengths are identified for each of the species represented in the etchants 408, the passivants 410, the target by-products 412, and the background by-products 414.

FIG. 5 provides an example embodiment 500 where a design of experiment (DOE) is executed to determine the most sensitive control knobs against variations in the product parameter. In block 502, a baseline (BL) recipe is selected. For embodiment 500, CD is again assumed to be the product parameter. For each of the steps (STEP_1 . . . STEP_n) within the recipe, there will be a setting for each control knob for the plasma processing tool. For the first step (STEP_1), these settings are represented by Knob_11, Knob_12 . . . Knob_1m. For the n^{th} step (STEP_N), these settings are represented by Knob_n1, Knob_n2 . . . Knob_nm. In block 504, adjustments (ΔKnob) are made to knob settings for the baseline (BL) recipe. In block 506, a DOE run is performed using the adjusted control knobs. In block 508, operational data is measured and collected for the DOE run. These measurements can include optical emission spectra (OES) data, ion measurement data, temperature data, pressure data, gas flow rate data, electrostatic chuck (ESC) temperature data, and/or other operational parameters. In block 510, CD measurements are made, and CD data is stored in block 512. This CD data is then used in block 514 to rank combinations of step and knob settings according to their sensitivity against CD variations. In block 516, a knob ranking is output that indicates which knob settings within which steps have the greatest impact on CD variation. For the example shown, the first knob for the first step (Knob_11) is ranked first followed by the second number for the third step (Knob_32). Other knobs would follow these two knobs in order of their determined rank. This knob ranking from block 516, the CD data from block 512, and the operational data from 508 are used in FIG. 6.

FIG. 6 provides an example embodiment 600 where the CD prediction model is built through regression analysis of operational data from block 508 that was measured and collected during the DOE runs as described in FIG. 5. The correlation between the ranked control knobs and the operational data from block 508 is also established. As described above, the operational data measured and collected through the processing diagnostic DOE runs as shown in block 508 of FIG. 5 can include a variety of different process related parameters. For example, this operational data can include optical emission spectra (OES) data, ion measurement data, temperature data, chamber pressure, gas flow rate, electrostatic chuck (ESC) temperature, and/or other operational parameters.

The operational data form block 508 is correlated in block 606 to changes in knobs as ranked in the knob rankings 516 from FIG. 5. Knob conversions 608 are generated from this correlation in block 606, and these knob conversions 608 indicate how much one or more knobs need to be adjusted to cause a desired change in CD. The knob conversions 608 are used in block 264 of FIG. 2B.

Through a regression analysis in block 602, the operational data from block 508 and the CD data from block 512 are processed to generate the CD prediction model. The regression analysis in block 602 is based in part upon the empirical results from CDs measured from the DOE runs in FIG. 5. As such, the resulting CD prediction model provides an accurate estimate of the CD based upon the operational data measured and collected from future runs without requiring a direct measurement of the CD for features on a process wafer using metrology tools. The resulting CD prediction model is used in block 260 of FIG. 2.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Microelectronic workpiece” as used herein generically refers to the object being processed in accordance with the invention. The microelectronic workpiece may include any material portion or structure of a device, particularly a semiconductor or other electronics device, and may, for example, be a base substrate structure, such as a semiconductor substrate or a layer on or overlying a base substrate structure such as a thin film. Thus, workpiece is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

The term “substrate.” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Systems and methods for processing a microelectronic workpiece are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method to adjust operation of a plasma processing tool, comprising:
before preventative maintenance (PM) for the plasma processing tool,
operating the plasma processing tool to run a process on a first test wafer; and
measuring pre-PM operational data associated with the process during the operating; and
after PM for the plasma processing tool,
operating the plasma processing tool to run the process on a second test wafer;
measuring post-PM operational data associated with the process during the operating;
applying a prediction model to the pre-PM operational data and the post-PM operational data to generate an estimated difference in a product parameter, the prediction model being configured to provide an estimate for the product parameter based upon measured operational data; and
adjusting one or more control settings for the plasma processing tool to compensate for the estimated difference in the product parameter.

2. The method of claim 1, wherein the measuring is performed using one or more sensors associated with the plasma processing tool.

3. The method of claim 2, wherein the one or more sensors are located outside a process chamber for the plasma processing tool, inside the process chamber, or both outside and inside the process chamber.

4. The method of claim 2, wherein the one or more sensors comprises an optical emission spectrometry (OES) sensor.

5. The method of claim 1, wherein the one or more control settings are configured to adjust process parameters for a process chamber for the plasma processing tool.

6. The method of claim 5, wherein the adjusting comprises adjusting a plurality of control knobs for the plasma processing tool.

7. The method of claim 5, wherein the one or more control settings are associated with at least one of microwave (MW) power, radio frequency (RF) power, gas chemistry flows, direct current (DC) biases, chamber pressure, or chamber temperature.

8. The method of claim 1, wherein the first and second test wafers comprise a blanket wafer having one or more material layers.

9. The method of claim 8, wherein the one or more material layers comprise at least one of a silicon oxide layer or a polysilicon layer.

10. The method of claim 1, wherein the prediction model is configured to estimate a critical dimension (CD) as the product parameter.

11. The method of claim 1, wherein the pre-PM operational data and the post-PM operational data each comprises at least one of optical emission spectrometry (OES) data, gas flow rate data, pressure data, or temperature data.

12. The method of claim 1, wherein the prediction model is based at least in part upon optical emission spectrometry (OES) wavelengths associated with etchants, passivates, or etch by-products associated with the process.

13. The method of claim 1, wherein the prediction model is based upon a determination of control settings that are most sensitive for the product parameter being estimated using the prediction model.

14. The method of claim 1, wherein the prediction model is based upon a regression on data collected in multiple experimental runs of the plasma processing tool.

15. The method of claim 1, further comprising matching one or more control settings across multiple plasma processing tools.

16. The method of claim 1, further comprising, after the PM for the plasma processing tool, repeating the operating, measuring, storing, applying, and adjusting until a target result is achieved for the product parameter.

17. The method of claim 16, wherein the target result comprises an estimated difference that is within an acceptable difference amount.

18. The method of claim 16, further comprising measuring the product parameter using a metrology tool after the repeating to determine if the target result for the product parameter is achieved.

19. The method of claim 1, further comprising performing the preventative maintenance.

20. The method of claim 19, wherein the preventative maintenance comprises at least one of replacing consumable parts, performing clean operations such as a wet clean operation, or pulling and re-sealing vacuum connections.
